(19) United States
(12) Patent Application Publication
(10) Pub. No.: US 2007/0148904 A1
(43) Pub. Date: Jun. 28, 2007

(54) DEVICE AND METHOD FOR CONTROLLING HIGH DENSITY PLASMA CHEMICAL VAPOR DEPOSITION APPARATUS

(76) Inventor: June Woo Lee, Seoul (KR)

Correspondence Address: SHERR & NOURSE, PLLC, 620 HERNDON PARKWAY, SUITE 200, HERNDON, VA, 20170, US

(21) Appl. No.: 11/616,711

(22) Filed: Dec. 27, 2006

(30) Foreign Application Priority Data
Dec. 28, 2005 (KR) 10-2005-0132759

(51) Int. Cl. H01L 21/76

(52) U.S. Cl. 438/424

(57) ABSTRACT

An HDP-CVD apparatus includes a valve assembly, a pump, and a control unit for adjusting the supply of He gas to be within a preset range through control of the valve assembly and the pump so that an actual wafer temperature, which was previously determined, is maintained at a preset temperature during a deposition process.

The present application claims priority under 35 U.S.C. 119 and 35 U.S.C. 365 to Korean Patent Application No. 10-2005-0132759 (filed on Dec. 28, 2005), which is hereby incorporated by reference in its entirety.

### BACKGROUND

A high density plasma chemical vapor deposition (HDP-CVD) apparatus is a semiconductor manufacturing apparatus, and more particularly a film or layer deposition apparatus which is primarily used to fill gaps between metal wires.

To produce the desired process temperature, the HDP-CVD apparatus uses plasma as a main heat source, unlike a regular chemical vapor deposition (CVD) apparatus, which uses a heater.

In the HDP-CVD apparatus, the backside of a wafer is cooled using He gas so that the temperature of a chamber does not exceed the temperature required for maintaining a metal pattern. For example, in the case of aluminum, a temperature of about 400° C. or less is required.

When the temperature of the wafer is not accurately detected, it is difficult for the HDP-CVD apparatus, which supplies the He gas, to maintain the temperature of the wafer within a desired range. Because of the huge temperature gradient from the backside of the wafer to the front, many techniques of temperature measurement would provide inaccurate or misleading results.

To solve the wafer temperature problem, techniques for uniformly maintaining the temperature of the wafer through uniform He supply, optical temperature measurement, and continuous He supply adjustment may be attempted. However, optical temperature measurement also suffers from inaccuracies, and the temperature reading may depend on the condition of the substrate (e.g., a bare wafer or a wafer having various patterns). Thus, errors related to temperature readings and temperature controls may result in a degradation of the manufacturing process.

### SUMMARY

Embodiments relate to high density plasma chemical vapor deposition (HDP-CVD) techniques, and more particularly, to a device and method for controlling an HDP-CVD apparatus, capable of uniformly controlling the temperature of a wafer by adjusting the supply of He gas.

Embodiments relate to a device and method for controlling an HDP-CVD apparatus, in which the amount of supplied He gas is automatically adjusted to accurately maintain the wafer at a preset temperature.

Embodiments relate to a valve assembly and a pump for supplying He gas to the backside of a wafer provided in the HDP-CVD apparatus, and a control unit for adjusting the supply of He gas to a preset amount through control of the valve assembly and the pump so that the wafer temperature is accurately maintained at a preset temperature during a deposition process.

Embodiments relate to a method of supplying gas to the backside of a wafer provided in an HDP-CVD apparatus, comprising adjusting the supply of He gas to be within a preset range so a previously determined wafer temperature is accurately maintained at a preset temperature during a deposition process.

### BRIEF DESCRIPTION OF THE DRAWINGS

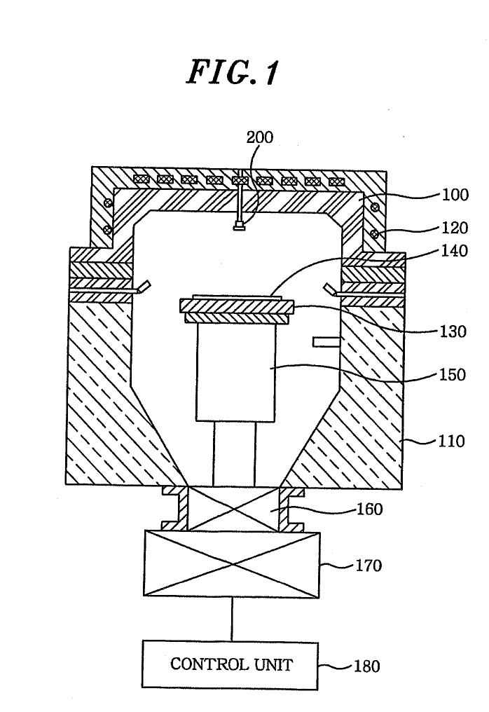

Example FIG. 1 schematically illustrates the device for controlling an HDP-CVD apparatus, according to embodiments;

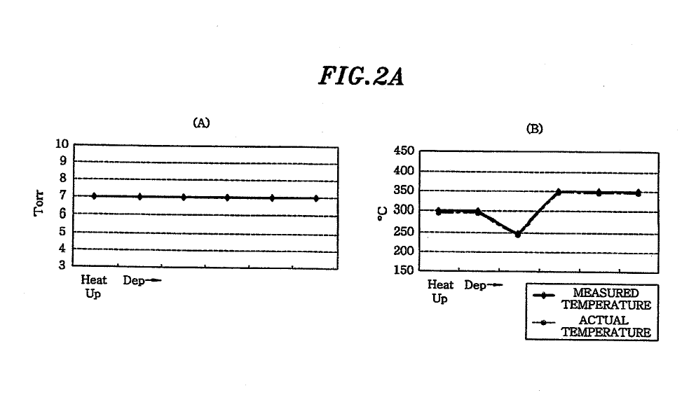

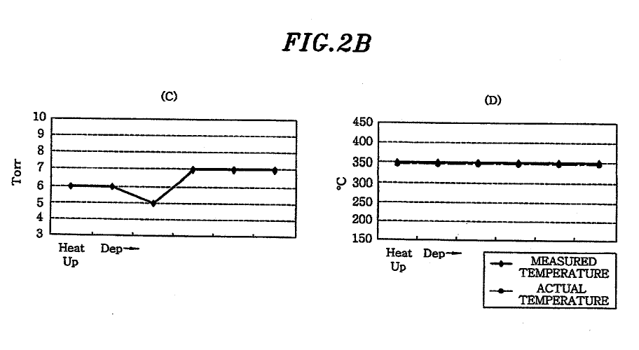

Example FIGS. 2A and 2B illustrate the results of a process of controlling an HDP-CVD apparatus, according to embodiments; and

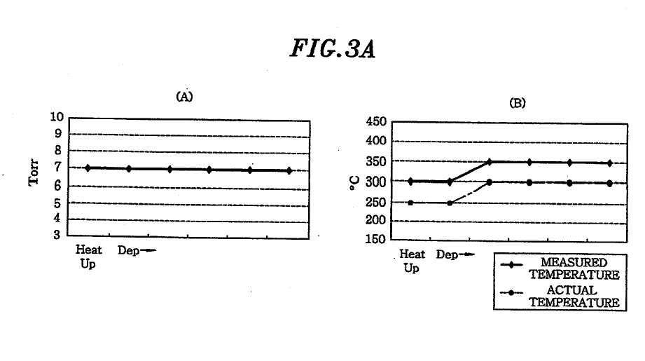

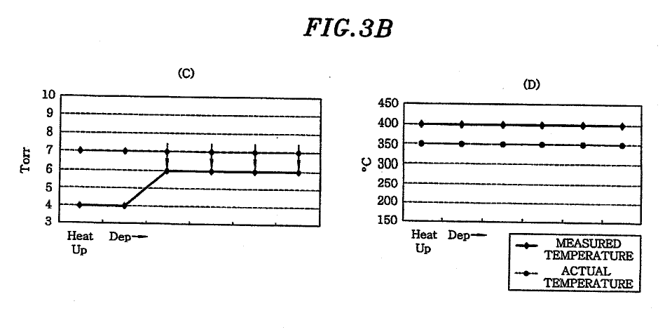

Example FIGS. 3A and 3B illustrate the results of a process of controlling an HDP-CVD apparatus, according to embodiments.

### DETAILED DESCRIPTION

As illustrated in FIG. 1, the HDP-CVD apparatus has an upper chamber 100 combined with a lower chamber 110 to thus form a complete enclosure, and an electrostatic chuck 130 on which a wafer 140 is mounted for a deposition process in the chambers 100, 110.

Under the electrostatic chuck 130, an intake and exhaust part 150 both supplies and exhausts He gas to and from the backside of the wafer for maintaining the wafer at a preset temperature. A valve assembly 160 and a pump 170 are sequentially mounted under the intake and exhaust part 150.

Radio frequency (RF) coils 120 for applying RF power are mounted in the upper portion and the side portion of the upper chamber 100. A spray nozzle 200 is mounted at the center of the upper portion of the upper chamber 100 for supplying reactant gasses necessary for a deposition process.

A plurality of spray nozzles 200 are mounted at the internal side surface of the lower chamber 110 for supplying reactant gasses, and an RF bias is applied to the lower chamber 110.

Further, the HDP-CVD apparatus includes a control unit 180 for automatically adjusting the amount of He gas to be supplied to the intake and exhaust part 150 via the valve assembly 160 and the pump 170. The control unit 180 operates with a programmed supply condition that depends on the difference between the actual temperature of the wafer and the measured temperature thereof.

Thus, in the HDP-CVD apparatus, the He gas is supplied to the backside of the wafer while the flow is automatically adjusted by the control unit 180 using a supply condition which depends on the difference between the actual wafer temperature and the measured temperature. Therefore, during the HDP-CVD process, the wafer temperature can be uniformly and accurately maintained at a temperature equal to or less than a preset temperature (e.g., 350° C. for the deposition of aluminum).

FIGS. 2A and 2B illustrate the results of the process of controlling an HDP-CVD apparatus.

As illustrated in FIG. 2A, a desired wafer temperature is set to be 350° C. for the deposition of an oxide film in a related art HDP-CVD apparatus. When the amount of He gas supplied to the backside of the wafer is maintained at about 7 torr, as shown in chart (A) in FIG. 2A, the actual temperature (●) of the wafer and the measured temperature (♦) are very close to each other and track each other in the range of 250˜350° C., as shown in chart (B) in FIG. 2A.

Accordingly, in the HDP-CVD apparatus, as illustrated in FIG. 2B, based on a previously determined experimental condition, or calibration procedure, in which the actual temperature (●) and the measured temperature (♦) change almost identically as in chart (C) of FIG. 2B, the amount of He gas which is supplied to the backside of the wafer is adjusted to 6 torr, 5 torr, and then 7 torr over time. Using this condition, as shown in chart (D) in FIG. 2B, the temperature of the wafer can be seen to be uniformly maintained at 350° C.

Turning now to FIGS. 3A and 3B, an example of the results of the process of controlling an HDP-CVD apparatus are shown.

As illustrated in FIG. 3A, a desired wafer temperature may be set to be 350° C. for the deposition of an oxide film in a related art HDP-CVD apparatus, even though the amount of He gas which is supplied to the backside of the wafer is maintained at about 7 torr as in (A), the actual temperature (●) of the wafer and the measured temperature (♦) have a difference of about 50° C. therebetween, as in (B).

Accordingly, in the HDP-CVD apparatus according to embodiments, as illustrated in FIG. 3B, based on a previously determined experimental condition or calibration procedure, that is, based on a condition in which there is a difference between the actual temperature (●) and the measured temperature (♦) of about 50° C., as in (C), the amount of He gas which is supplied to the backside of the wafer is adjusted to 4 torr and then 6 torr over time. If this is done, as shown in chart (D) of FIG. 3B, the actual temperature (●) of the wafer can be seen to be uniformly maintained at 350° C.

As described above, embodiments relate to a device and method for controlling an HDP-CVD apparatus. According to embodiments, using an HDP-CVD process, the amount of He gas to be supplied to the backside of a wafer is automatically adjusted so that the actual wafer temperature, which is previously determined during an experimental or calibration procedure, is maintained at a preset temperature. Thereby, the temperature of the wafer can be uniformly maintained at the preset temperature.

Therefore, the amount of He gas may vary depending on the type of wafer or process used. The data for each case is gathered by conducting a preliminary experiment, then programmed into control unit 180. Thus the temperature of the wafer required in practice can be accurately and uniformly maintained with any type of wafer, product group or process, thereby increasing the preparation yield of the HDP-CVD apparatus.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A device comprising:
a valve assembly and a pump for supplying He gas to the backside of the wafer provided in a high density plasma chemical vapor deposition apparatus; and
a control unit for adjusting a supply of the He gas to be within a preset range through control of the valve assembly and the pump so that an actual wafer temperature, which is previously determined, is maintained at a preset temperature during a deposition process.

2. The device of claim 1, wherein, when the actual wafer temperature, which is previously determined, is identical with a measured temperature, the supply of the He gas is adjusted to be within a preset range, wherein the preset range depends on a change in the two identical temperatures.

3. The device of claim 1, wherein, when the actual wafer temperature, which is previously determined, is not identical with a measured temperature, the supply of the He gas is adjusted to be within a preset range so that the actual wafer temperature coincides with a preset temperature.

4. The device of claim 1, wherein the actual wafer temperature is previously determined by a calibration procedure.

5. A method of controlling a high density plasma chemical vapor deposition apparatus, suitable for supplying gas to a backside of a wafer provided in the high density plasma chemical vapor deposition apparatus, comprising:
adjusting a supply of He gas to be within a preset range so that an actual wafer temperature, which is previously determined, is maintained at a preset temperature during a deposition process.

6. The method of claim 5, wherein, when the actual wafer temperature, which is previously determined, is identical with a measured temperature, the supply of the He gas is adjusted to be within a preset range, wherein the preset range depends on a change in the two identical temperatures.

7. The method of claim 5, wherein, when the actual wafer temperature, which is previously determined, is not identical with a measured temperature, the supply of the He gas is adjusted to be within a preset range so that the actual wafer temperature coincides with a preset temperature.

8. The method of claim 5, wherein the actual wafer temperature is previously determined by a calibration procedure.
